(19) United States
(12) Patent Application Publication
(10) Pub. No.: US 2026/0302147 A1
(43) Pub. Date: Oct. 1, 2026

(54) ONLINE ADJUSTMENT OF MAGNET BARS IN MAGNETRONS

(71) Applicant: SOLERAS ADVANCED COATINGS BV, Deinze (BE)

(72) Inventors: Wilmert DE BOSSCHER, Drongen (BE); Koen CORTEVILLE, Izegem (BE)

(21) Appl. No.: 19/477,353

(22) PCT Filed: Apr. 30, 2024
(86) PCT No.: PCT/EP2024/061883

§ 371 Date: Oct. 21, 2025

(30) Foreign Application Priority Data
May 4, 2023 (BE) 2023/5361

(51) Int. Cl. H01J 37/34; C23C 14/35; C23C 14/54

(52) U.S. Cl. CPC H01J 37/3444; C23C 14/35; C23C 14/54; H01J 37/3405; H01J 2237/332

(57) ABSTRACT

A control assembly for controlling the magnetic structure of a magnetron sputter apparatus, an inline sputter coating apparatus including the same, and a related coating method are disclosed. The assembly includes an elongate support structure, and, coupled thereto, at least one control unit, at least one storage device and at least one actuator for locally adjusting a position and/or orientation of the magnetic structure. An input connector of the control unit is operatively connectible to a trigger unit disposed distantly to the assembly. The control unit is configured to load control inputs from the storage device, determine a control trajectory for the actuators based on the control inputs, generate a sequence of control signals for the actuators in accordance with the control trajectory, and synchronize a transmission of the sequence of control signals to driver circuits of actuators with at least one trigger signal from the trigger unit.

### FIELD OF THE INVENTION

The present invention relates to the field of magnetron sputtering processes, magnetron sputter equipment and coatings obtained thereby. More specifically, the invention relates to control assemblies for magnetic structures in magnetrons that can be adjusted dynamically.

### BACKGROUND OF THE INVENTION

Magnetron sputtering is a material layer deposition technique that uses the plasma confinement effect of magnetic field tunnels to achieve high plasma densities and related sputter deposition rates. Sputter coating equipment has been successfully adapted to meet industrial needs of coating large-area substrates in little time, and yet achieving good control over film properties such as thickness uniformity. Therefore, number of industries, ranging from flat panel display technology (LCD or OLED or touch technology) to low-emissivity and anti-reflective glass coating, rely on magnetron sputter techniques during product manufacture. Continuous sputter coating with inline deposition systems, in which the substrate moves relative to the sputter target, are offering the benefits of high throughput and flexibility. Complex coating stacks, e.g. multi-layered coatings having a varying number of coating layers and/or different coating layer compositions, can be reliably sputtered onto moving substrates that are transported across multiple sputter targets arranged in a same deposition chamber or different deposition chambers along the coating line.

It has proven useful to provide magnetrons whose magnetic structure can be adjusted locally, without having to vent the coating apparatus, such that not only imperfections of the resulting magnetic field and the thereby induced plasma racetrack can be corrected more efficiently before and during a production campaign, but also erosion profiles on the sputter target surface can be compensated in an automized fashion. The main purpose of tuning the magnetic structure locally is to control and improve uniformity of a layer property (e.g. thickness) across the moving substrate.

Document WO 2015/167687 A1 (SPUTTERING COMPONENTS INC [US]), 5 Nov. 2015, discloses a magnetron assembly which comprises an elongated support structure, a magnet bar structure movably positioned below the support structure, and a plurality of drive modules with motorized actuation mechanisms coupled to the support structure. An electronic controller and rechargeable battery module are coupled to the support structure and in operative communication with the drive modules. The battery is configured to energize each motorized actuation mechanism and the electronic controller and is recharged by power generation modules that are coupled to the support structure.

Document EP3963620 A1 (INTERPANE ENTW UND BERATUNGSGESELLSCHAFT MBH [DE]), 9 Mar. 2022, discloses a magnetron assembly which comprises a plurality of magnets attached to a plurality of yokes. Actuating mechanisms are attached along an elongated support bar and driving modules for the actuating mechanisms are configured to displaces the yokes individually away from and/or toward the elongated support bar. An external controller with processor, arranged outside the vacuum chamber, is configured to automatically determine positions of each of the plurality of yokes on the basis of parameters that define a coating profile for the substrate. A signal comprising the determined yoke positions is sent from the external controller to the magnetron assembly through an optical interface fibre; a master controller within the magnetron assembly receives the signal from the optical interface fibre and sends it to a plurality of slave controllers in operative communication with the plurality of driving modules. A rechargeable battery, in operative communication with the driving modules, is configured to energize the actuation mechanisms, the slave controllers and the master controller.

In the above-mentioned documents, the tuning rate of the magnetic structures inside the magnetron assembly is still limited and the rechargeable battery may have to be replaced regularly due to its finite cycle life.

It is therefore desirable to further reduce tuning rate limitations in online adjustable magnet bar assemblies.

### SUMMARY OF THE INVENTION

Though not being perceived as a bottleneck in simple sputter-coating applications, the inventors found that a limited amount and rate of data to be transferred across a dedicated communication interface between the magnet bar assembly and the thereto connected end block (outside of the magnet bar assembly) have a negative impact on sputter-coating applications in which a complex dynamic tuning of the magnetic structure is desired. A complex tuning pattern may be required to ensure good uniform coating on moving 3D-shaped or curved substrates. It is thus desirable to have a no-conflict solution, capable of providing a sequence of tuning parameters in a robust and reliable way without excessive loading of the communication interface.

It is an object of embodiments of the present invention to provide devices and methods for magnetrons that allow online adjustments of a magnet bar at higher control rates.

The above objective is accomplished by an assembly, apparatus and method according to the present invention.

In a first aspect, the present invention relates to a control assembly for controlling the magnetic structure of a magnetron sputter apparatus. The assembly is connectible to an end block of the magnetron sputter apparatus and comprises an elongate support structure having a length axis. Coupled to the support structure, the control assembly further comprises at least one control unit, at least one storage device and at least one actuator for locally adjusting a position and/or orientation of the magnetic structure when operatively coupled to the at least one actuator. An input connector of the at least one control unit is operatively connectible to a trigger unit that is disposed distantly to the control assembly. Furthermore, the at least one control unit is configured to:
load control inputs from the at least one storage device, wherein control inputs comprise setpoints for the at least one actuator or data required for the calculation of setpoints for the at least one actuator;
determine a control trajectory for the at least one actuator based on the loaded control inputs; generate a control signal, or sequence of control signals, for the at least one actuator in accordance with the control trajectory; and
synchronize a transmission of the control signal, or the sequence of control signals, to a driver circuit of the at least one actuator with at least one trigger signal from the trigger unit.

The trigger signal for synchronization with the control signal transmission is indicative of a position of a substrate relative to the magnetic structure.

Here, the trigger signal being indicative of the substrate position relative to the magnetic structure means conveying substrate position information or substrate position data that is either embedded in the trigger signal or is derivable from the trigger signal as such. In embodiments of the invention, this encompasses the transmission of substrate position information as part of the trigger signal content, e.g. substrate position information encoded in the trigger signal, as well as providing a hint to the substrate position which is derivable from or implied by the trigger signal as such, without an actual and explicit transfer of the substrate position data by the trigger signal. In the former case, the position information is carried by the trigger signal and can be expressed in a local coordinate system of the magnetic structure, or can be transformed into such local coordinate system. In the latter case, not the content carried by the trigger signal but the trigger signal as such, i.e. the signal as a whole being identified as a trigger signal issued by the trigger unit, provides a hint as to where the substrate can be found at that particular moment in time, without requiring the transmission of substrate position data as explicit content of the trigger signal. In embodiments of the invention, a hint to the substrate position is derivable from the trigger signal if the trigger unit is responsive to the presence of the substrate at a particular position relative to the magnetic structure, by emitting the trigger signal, and if the trigger unit can be identified as the source of the trigger signal, e.g. by analyzing the trigger signal. For example, the trigger signal may correspond to a message and the trigger unit is identified in a source field of the message, or the trigger unit as source of the trigger signal may be inherently expressed through the unique format, duration, variation or any other suitable signal characteristic of the trigger signal.

The present invention further relates to a magnetron sputter apparatus for sputter-coating of a non-flat substrate and an inline vacuum sputter coating apparatus for generating repetitive and reproducible coating profiles on moving substrates, which comprise a control assembly according to the first aspect.

In embodiments of the invention, the magnetron sputter apparatus is adapted to receive cylindrically shaped targets.

In yet another aspect, the present invention relates to a method of sputter-coating a moving substrate, using a magnet bar assembly for a magnetron sputter apparatus. The magnet bar assembly comprises at least one actuator for locally adjusting a position and/or orientation of an elongate magnetic structure of the magnet bar assembly. The method comprises the steps of:
storing control inputs in a storage device arranged inside the magnet bar assembly, wherein the control inputs comprise setpoints for the at least one actuator or data required for the calculation of setpoints for the at least one actuator;
loading the control inputs from the storage device into a control unit arranged inside the magnet bar assembly;
receiving an external trigger signal from a trigger unit disposed distantly to the magnet bar assembly;
executing a control program on the control unit to determine a control trajectory for the at least one actuator based on the control inputs, generate a control signal or a sequence of control signals for the at least one actuator in accordance with the control trajectory, and synchronize a transmission of the control signal or the sequence of control signals to a driver circuit of the at least one actuator with the external trigger signal;
adjusting the position and/or orientation of magnetic structure while sputter-coating the moving substrate, by driving the at least one actuator in accordance with the control signals or the sequence of control signals.

It is an advantage of embodiments of the present invention to provide a sequence of tuning parameters in a robust and reliable way without excessive loading of the communication interface.

In embodiments of the invention, the control trajectory for each control assembly actuator comprises at least one regulation position for the actuator and typically comprises a list of regulation position for the actuator over an exposure interval associated with a moving substrate to be coated. Likewise, the control unit generates at least one control signal in accordance with the control trajectory of the actuator, but typically generates a sequence of control signals in accordance with the control trajectory of the actuator.

According to some embodiments of the invention, the support structure may comprise or consist of a hollow tubular support element, an extrusion profile, a bent sheet metal part, or a combination of extrusion profile and bent sheet metal.

In some embodiments of the invention, the support structure provides a fluid-tight housing for the magnetic structure and the electronic components including the control unit(s), the storage device(s), the driver circuits and associated actuators, and other optional components (e.g. receiver circuitry), protecting them from damage and corrosion. The support structure may be adapted for distributing a coolant fluid cooling over the complete length of the support structure, e.g., by means of fluid-tight ducts arranged inside the outer circumferential wall of the support structure.

According to some embodiments of the invention, a magnet bar assembly is formed upon coupling the magnetic structure to the control assembly. This coupling may be an indirect coupling, e.g., via one or more actuators of the control assembly. In such embodiments of the invention, the magnetic structure is directly or indirectly affixed to the control assembly actuators.

According to some embodiments of the invention, the magnetic structure may comprise a magnetic pole piece or a nonmagnetic piece as a carrier structure onto which arrays of magnets are placed. These arrays of magnets may be organized into rows over a central portion of a longitudinally extending magnetic structure. Preferably, a central row of magnets is flanked by two peripheral rows of magnets, wherein the orientation of magnetic poles of the magnets in the central row is opposite to the orientation of magnetic poles of the magnets in the peripheral rows. The control assembly actuators may be coupled or attached to the magnetic pole piece or nonmagnetic carrier so that they cause a local deformation of the magnetic pole piece or nonmagnetic carrier. A gear reduction ratio associated with the control assembly actuators may be advantageously decreased when deforming a nonmagnetic carrier or holding structure for the magnets of the magnetic structure or when displacing, e.g. lifting, the magnets of the magnetic structure relative to this nonmagnetic carrier.

According to some embodiments of the invention, the magnetic structure may comprise multiple segments. The segmentation of the magnetic structure may be lengthwise (e.g. in a direction corresponding to an axis of elongation of the support structure), crosswise (e.g. in a direction perpendicular to the axis of elongation of the support structure), oblique, sideways, or any combination thereof. Moreover, this segmentation may be confined to specific zones of the magnetic structure (e.g. end zones, middle zone) or extend to all zones of the magnetic structure. The individual segments of the magnetic structure may be acted on locally by corresponding actuators of the control assembly.

According to same or different embodiments of the invention, the magnetic structure may be subdivided into multiple elongate sections or strips such that each elongate section of the magnetic structure has its own magnetic or nonmagnetic carrier onto which the magnets of one of the magnet arrays are placed, e.g. the magnets of the central or one of the peripheral magnet rows.

Actuators of the control assembly may act on the different sections of the magnetic structure to locally change their respective positions and/or orientations in one or several tuning points, e.g. along the length axis of the support structure. For each tuning point, a separate actuator of the control assembly may be provided with respect to the each one of the different segments of the magnetic structure to locally change the position and/or orientation of the segment. Alternatively, a single actuator of the control assembly may be provided for each tuning point, e.g. along the length axis of the support structure, with respect to the each one of the different segments of the magnetic structure to locally change the position of the segment; a hinge system may be coupled to this actuator to further allow a tilting movement of the different segment of the magnetic structure relative to each other.

According to some embodiments of the invention, the at least one control unit comprises a processing unit as subunit or is operatively coupled to a processing unit within the control assembly. The processing unit may be used to perform computational tasks such as, but not limited to, the application of transformation functions to loaded setpoints, the adjustment of control trajectories, or the computation of setpoints from grid data pertaining to a substrate property or type (e.g. topographical substrate data), which reduces the computational burden on the control unit(s). More particularly, in order to allow for the adjustment of control trajectories, the at least one control unit may further be configured to: load a record of one or more process variables pertaining to the magnetron sputter apparatus from the at least one storage device or from the trigger unit through the input connector, and adjust the control trajectory based on said record of said one or more process variables. This adjustment may be carried out directly on the record value as input, or via intermediate calculation results obtained from the record value in combination with addition input data.

According to some embodiments, several of the electronic components, including the control unit(s), the storage device(s), the processing unit(s) and/or the driver circuit(s) may be assembled on the same circuit board or embedded into the same electronic package.

According to some embodiments of the invention, electrically powered components of the control assembly such as the driver circuits, electrically driven actuators, the at least one control unit and storage device may be powered by an electrical transmission line, e.g., a single electrical wire or wire bundle, which extends between control assembly and an end block system to which the control assembly can be connected. Preferably, power line modulation techniques are used to also allow the exchange of data between the at least one control unit of the control assembly and the end block system. This reduces the amounts of wired connections between the control assembly and the end block system, and/or the amount of communication interface modules (e.g. transceiver or transmitter/receiver modules).

In embodiments of the invention, the trigger unit may be sensor unit, e.g. event-triggerable sensor units such as substrate position or speed sensors. In other embodiments of the invention, the trigger unit may be part of the deposition chamber, e.g., a valve of an entrance or exit slit that is capable of generating trigger signals when switching or reaching a predetermined state, e.g. open state. In yet other embodiments of the invention, the trigger unit may be part of the substrate transport system such as robot arm carrying the substrate or a position sensor in a motor of the transport system.

The trigger signal may convey absolute substrate position data to the at least one control unit, or contains data that enables the at least one control unit to derive a position of the substrate relative to the control assembly. In some embodiments of the invention, the at least one control unit may be configured to extract substrate position information from the trigger signal. Additionally or alternatively, the at least one control unit may be configured to extract sender information from the trigger signal, correlate the sender information with a position of the moving substrate or retrieve the position of the moving substrate from the sender information. The trigger signal may correspond to a well-defined position of the substrate, e.g., a homing signal. Additional information such as substrate speed information and/or current process parameters and equipment settings may be included in the trigger signal or derivable therefrom.

In embodiments of the invention, the complexity of the trigger signal may range from an interrupt request, e.g. single pulse, to a signal train, e.g. pulse train, implementing a predetermined data format or following a communication protocol.

The at least one control unit may be configured to determine a time basis for the transmission of the control signals from substrate speed information or substrate trajectory data, which the at least one control units either loads from the at least one storage device or extracts from the trigger signal.

In embodiments of the invention, the at least one control unit may be configured to determine the time intervals between the transmission of consecutive control signals based on precalculated substrate trajectory data accessible on the at least one storage device, or based on one or more received trigger signals. The precalculated substrate trajectories define waypoints (substrate position) which are combined with substrate speed information or passage times, included in the precalculated substrate trajectories or in the trigger signal.

In embodiments of the invention, the at least one control unit may synchronize the transmission of the first control signal with the trigger signal or, in the case of recurrent control sequences, the transmission of any one of the control signals in the sequence. Advantageously, the transmission of multiple control signals is synchronized by the control unit with the trigger signal or with a sequence of trigger signals. This allows improved synchronization between the online adjustment of the magnetic structure with the movement of the substrate. Synchronization by the at least one control unit may include determining the delay or delays at which the control signal or control signals are transmitted relative to the trigger signal event or the reception of the trigger signal by the control unit.

In embodiments of the invention, the control inputs stored on the at least one storage device may be setpoint or lists of setpoints with respect to each control assembly actuator. The control inputs, more particularly the actuator setpoints, may be organized into tables or table-like data structures, e.g. look-up tables. Metadata or a unique identifier may be associated with each one of tables or table-like data structures stored on the at least one storage device, which links the table or table-like data structure to a specific combination of sputter process parameters, sputter equipment parameters, and/or substrate parameters, or ranges of such parameter. The at least one control unit may access the control inputs in the tables or table-like data structures based on the metadata or a unique identifier. In particular embodiments of the invention, at least part of the current sputter process parameters may be encoded in and conveyed by the trigger signal that is generated by the trigger unit, thereby allowing the control unit to retrieve the appropriate control inputs from the at least one storage device.

In embodiments of the invention, the at least one control units may apply a transformation to the control inputs loaded from the at least one storage device. The applied transformation optimizes the control trajectories with respect to additional input variables, such as substrate related information (e.g. size, orientation, curvature values and/or topography mappings) and/or processing conditions. In such embodiments, the at least one control unit is configured to extract the additional input variables from the trigger signal(s), extract the additional input variables from external data frames that are communicated to the control unit, or retrieve the additional input variables from the at least one storage device if available.

The at least one control unit may compare the trigger signal, a unique identifier obtained from the trigger signal and/or sender information to corresponding entries in the table-like structures that are stored on the at least one storage device and retrieve the actuator setpoints associated with an entry that matches.

It is an advantage of embodiments of the invention that the amount of external data to be communicated through a noisy communication link between the control unit of the control assembly and an end block in connection with the control assembly can be reduced.

It is an advantage of embodiments of the invention that higher-frequency signals can be used for communication between the components of the control assembly compared to the lower-frequency signals available for communication between the end block and the magnet bar assembly in conventional magnetrons. This allows for data exchange at higher transfer rates between the electronic components inside the control assembly, e.g. between the control unit and the driver circuits and between the control unit and the storage device. Indeed, the support structure may form a protective enclosure for the electronic components of the control assembly and advantageously acts as an electromagnetic Faraday cage with respect to noise interferences from the power supply source and plasma. Excessive shielding of wirings between the electronic components inside the control assembly is thus no longer required.

It is an advantage of embodiments of the invention that the control signals to be transmitted to the driver circuits of the actuators of the control assembly are generated by the control unit within the control assembly and only propagate on signaling means disposed within the control assembly. No communication with external devices is required, in particular external devices that are located outside the vacuum chamber of the sputter apparatus. Control signals which relate to local autonomous adjustments of the magnetic structure along the magnet bar thus no longer have to originate from outside the control assembly—that is from outside the magnet bar, magnetron, end-block or even the vacuum chamber—but can be generated and distributed in situ, inside the magnet bar. No outside information is required for adjusting the magnetic structure in an autonomous manner.

It is a further advantage of embodiments of the invention that control signals can be defined, generated and transmitted at a large bandwidth within the magnet bar. Moreover, a high-bandwidth communication channel, e.g. connector, between the magnet bar and the end block or between the magnet bar and the outside of the vacuum chamber is no longer required.

It is an advantage of embodiments of the invention that actuators of the control assembly can be regulated in real time while sputter-coating substrates. This allows substrates with a curved coating surface to be coated uniformly.

It is an advantage of embodiments of the invention that multiple substrates of different height (thickness) or surface orientation can be sputter-coated in parallel, e.g. if mounted on a common transport frame or arranged into columns that are substantially parallel to the length axis of the rotary target.

It is an advantage of embodiments of the invention that control inputs such as actuator setpoints can be transformed in situ by the control unit and/or control trajectories for the actuators of the control assembly can be adjusted in site by the control unit. This allows calibration and feedback control operations to be carried out efficiently.

It is an advantage of embodiments of the invention that control trajectories can be updated or re-adjusted easily under any change in the sputter process conditions, the equipment settings and/or the substrate properties. This reduces the time necessary for optimizing in a new process, for tuning in the sputter process at the start of a new production campaign, or to adapt the sputter apparatus to a change of product or substrate shape during one and the same production campaign.

It is an advantage of embodiments of the invention that a coating layer can be deposited uniformly over large areas of substrates or workpieces that are non-flat, e.g. curved or having a varying height profile, or mounted at an angle relative to a substrate carrier plane or substrate transport direction. Typical width and length dimensions of (curved) large-area substrates are, e.g., 0.15*0.3m², 0.3*0.4 m², 1.1*1.3 m², 1.5*1.8 m², 1.0*3.0 m², 2.0*2.0 m², 2.0*3.0 m² or up to 3.5*6.5 m². It is a further advantage of embodiments of the invention that the deposited layer thickness on large-area, non-flat or inclined substrates can be controlled accurately, e.g. within +/−5% or less, e.g. accurate within +/−3% or even +/−1%.

Particular and preferred aspects of the invention are set out in the accompanying independent and dependent claims. Features from the dependent claims may be combined with features of the independent claims and with features of other dependent claims as appropriate and not merely as explicitly set out in the claims.

For purposes of summarizing the invention and the advantages achieved over the prior art, certain objects and advantages of the invention have been described herein above. Of course, it is to be understood that not necessarily all such objects or advantages may be achieved in accordance with any particular embodiment of the invention. Thus, for example, those skilled in the art will recognize that the invention may be embodied or carried out in a manner that achieves or optimizes one advantage or group of advantages as taught herein without necessarily achieving other objects or advantages as may be taught or suggested herein.

The above and other aspects of the invention will be apparent from and elucidated with reference to the embodiment(s) described hereinafter.

### BRIEF DESCRIPTION OF THE DRAWINGS

The invention will now be described further, by way of example, with reference to the accompanying drawings, in which:

FIG. 1 is a cutaway view of a control assembly with magnetic structure, in accordance with an embodiment of the invention.

FIG. 2 and FIG. 3 are enlarged views of the control assembly of FIG. 1, showing more details.

FIG. 4 is a cross-section of an inline sputter coating apparatus that comprises a control assembly according to an embodiment of the invention.

FIG. 5 illustrates the steps of a coating method that uses a control assembly for magnetic structures of magnetrons in accordance with embodiments of the invention.

FIG. 6 illustrates the steps of a method for updating the control trajectories, which can be used in embodiments of the invention.

The drawings are only schematic and are non-limiting. In the drawings, the size of some of the elements may be exaggerated and not drawn on scale for illustrative purposes. The dimensions and the relative dimensions do not necessarily correspond to actual reductions to practice of the invention.

Any reference signs in the claims shall not be construed as limiting the scope.

In the different drawings, the same reference signs refer to the same or analogous elements.

### DETAILED DESCRIPTION OF ILLUSTRATIVE EMBODIMENTS

The present invention will be described with respect to particular embodiments and with reference to certain drawings but the invention is not limited thereto but only by the claims.

The terms first, second and the like in the description and in the claims, are used for distinguishing between similar elements and not necessarily for describing a sequence, either temporally, spatially, in ranking or in any other manner. It is to be understood that the terms so used are interchangeable under appropriate circumstances and that the embodiments of the invention described herein are capable of operation in other sequences than described or illustrated herein.

It is to be noticed that the term “comprising”, used in the claims, should not be interpreted as being restricted to the means listed thereafter; it does not exclude other elements or steps. It is thus to be interpreted as specifying the presence of the stated features, integers, steps or components as referred to, but does not preclude the presence or addition of one or more other features, integers, steps or components, or groups thereof. Thus, the scope of the expression “a device comprising means A and B” should not be limited to devices consisting only of components A and B. It means that with respect to the present invention, the only relevant components of the device are A and B.

Reference throughout this specification to “one embodiment” or “an embodiment” means that a particular feature, structure or characteristic described in connection with the embodiment is included in at least one embodiment of the present invention. Thus, appearances of the phrases “in one embodiment” or “in an embodiment” in various places throughout this specification are not necessarily all referring to the same embodiment. Furthermore, the particular features, structures or characteristics may be combined in any suitable manner, as would be apparent to one of ordinary skill in the art from this disclosure, in one or more embodiments.

Similarly it should be appreciated that in the description of exemplary embodiments of the invention, various features of the invention are sometimes grouped together in a single embodiment, figure, or description thereof for the purpose of streamlining the disclosure and aiding in the understanding of one or more of the various inventive aspects. This method of disclosure, however, is not to be interpreted as reflecting an intention that the claimed invention requires more features than are expressly recited in each claim. Rather, as the following claims reflect, inventive aspects lie in less than all features of a single foregoing disclosed embodiment. Thus, the claims following the detailed description are hereby expressly incorporated into this detailed description, with each claim standing on its own as a separate embodiment of this invention.

Furthermore, while some embodiments described herein include some but not other features included in other embodiments, combinations of features of different embodiments are meant to be within the scope of the invention, and form different embodiments, as would be understood by those in the art.

In the description provided herein, numerous specific details are set forth. However, it is understood that embodiments of the invention may be practiced without these specific details. In other instances, well-known methods, structures and techniques have not been shown in detail in order not to obscure an understanding of this description.

In the context of the present invention, a non-flat substrate surface to be coated comprise at least one non-zero principal curvature and related direction of principal curvature. This includes substrate surfaces or surface portions whose shape varies in discrete steps, e.g. in which a discrete approximation to the principal curvature direction can be defined, are also encompassed. A back surface of the substrate to be coated does not need to be curved, i.e. can be flat. Sharp or obtuse angles, e.g. edges, between otherwise flat, but possibly inclined surface portions of the substrate are considered surfaces with localized infinite curvatures and also fall under the scope of the present invention. Examples are multi-facetted surfaces or meshed created from a collection of triangles, quadrilaterals or the like, which may approximate a smooth surface.

Designs for wind shields, sunroofs, large display panels and dashboards in the automotive sector are often using complex shapes, characterized by a non-flat, curved surface geometry. Ultrawide computer screens with a curved display area are also commercialized. As for conventional flat substrates, these curved or non-flat substrate surfaces, too, are usually equipped with anti-reflection coatings, protective coatings, or the like. Not only the large-sized area of substrates or workpieces over which a coating layer has to be deposited uniformly is impressive for these applications, e.g., 0.15*0.3 m², 0.3*0.4 m², 1.1*1.3 m², 1.5*1.8 m², 1.0*3.0 m², 2.0*2.0 m², 2.0*3.0 m² or up to 3.5*6.5 m², but also the stringent tolerances on the layer thickness uniformity are. It is not unusual that product manufactures ask for magnetron sputter equipment that is capable of controlling the deposited layer thickness on the substrate accurately within +/−5% or less, e.g. to be accurate within +/−3% or +/−1%. The curved geometry and complex substrates shapes for which uniform coating is required, makes the tight control of coating layer thickness uniformity in magnetron sputter equipment even more challenging.

Historically, sputter coatings for these applications have been deposited on flat substrates prior to a bending process. More recently, substrates to be coated may be bent and treated beforehand, and coating is executed subsequently on the curved substrates. The coating layer thickness uniformity can in principle be controlled through a local tuning of the magnet bar inside the magnetron. However, the relatively high speeds at which the substrates are transported through the deposition chamber of an inline coater, e.g. of the order of meters per minute, often is beyond the tuning capabilities of conventional magnetons, in which control data is sent through a noisy communication channel that relays the magnet bar assembly to the end block and the external control devices outside the vacuum chamber. This limits the rate at which control data can be communicated to the actuators of the adjustable magnet bar assembly. Embodiments of the invention described hereinunder solve the problem of limited transfer rates for control data that needs to be communicated to the actuators inside the magnet bar assembly.

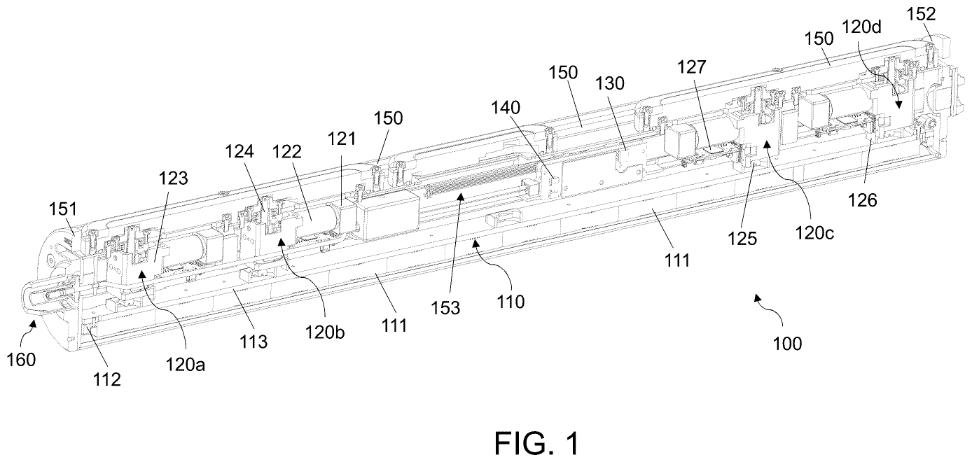

FIG. 1 shows a control assembly for the magnetic structure of a magnet bar in a cutaway view. The control assembly 100 comprises an elongate support structure 150 in the form of a tubular housing, a control unit 130, a storage device 140, and actuators 120a-d for locally adjusting a position and/or orientation of the magnetic structure 110. The control unit 130, storage device 140, and actuators 120a-d are arranged in the interior of the elongate support structure 150 and coupled to the support structure 150, e.g., coupled in a way such that they have a fixed longitudinal position on a center axis of the tubular support structure.

The elongate support structure may be provided in many different forms and shapes, such as, but not limited to, an extrusion profile, a hollow tube or pipe, a rolled metal sheet, or a combination of these. One or more of the control unit 130, storage device 140, and actuators 120a-d may be firmly attached onto mounting plates that are secured, e.g. screwed, to an outer or inner wall of the support structure. The outer and inner walls may be arranged to divide the inner volume of the support structure into a plurality of longitudinally extending cavities or compartments. At least some of the compartments are separated from a fluid path of a coolant fluid, thus protecting electronic components from corrosion and electrically isolating them from the high absolute voltages (e.g. above 200 V, typically above 300 V, such as 400 V, and up to 1000 V under special conditions) when supplying the target of a magnetron sputter apparatus with high electrical power under sputtering conditions. In the present embodiment, the elongate support structure comprises at least one such compartment 153. End pieces 151, 152, e.g. end caps or discs, can be mounted on respective end portions of the support structure 150 to completely shield the interior of the support structure, which may be operated under atmospheric pressure conditions, from the surrounding vacuum conditions that typically govern the interior of a deposition chamber comprising the magnet bar to which the support structure belongs. When mounted inside the support structure 150, the magnetic structure 110 and the control assembly 100 together form a magnet bar assembly that can be used in magnetron sputter apparatuses or magnetron-based inline sputter coating systems.

In the present embodiment, the magnetic structure 110 comprises a pole piece 113, e.g. comprising a soft iron or other magnetic permeable material (e.g. Nickel, Cobalt, etc.) material, an inner or central array of magnets 111, e.g. rare-earth permanent magnets, and an outer or peripheral array of magnets 112 surrounding the central array of magnets 111 to create a magnetic racetrack configuration adjacent to an outer surface circumferential wall of the support structure. Both the inner and the outer array of magnets are typically mounted onto the same side of the pole piece. When the magnet bar assembly is used in conjunction with a sputter target in sputter coating processes, the magnetic racetrack configuration causes the formation of a plasma confinement region, e.g. a plasma racetrack, in the vicinity of the target surface that is circumferentially enclosing the magnet bar assembly. The magnetic structure 110 may be segmented, e.g. comprise several consecutive segments that are arranged in a linear fashion along the length axis, width axis or diagonal axis of the elongate support structure. For instance, respective end portions and a central portion of the magnetic structure may be segments, which facilitates the exchange of differently shaped end portions for different target designs, e.g. to conform better to dog bone shaped targets. Although shown as a flat structure, the pole piece may be angled towards its outer rim or may be curved to better conform with the circular cross-sectional shape of the tubular support structure and/or target tube. Alternatively, the radially outwards oriented faces of the magnets composing the inner and/or outer array of magnets may have an angled or curved surface geometry.

Actuators 120a through 120d may be provided in the same or in different compartments of the support structure and their respective longitudinal locations are distributed over the length of the support structure 150. The actuators 120a-d preferably are electrically driven actuators, for instance electrical motors with a linear drive mechanism or coupled to a linear drive mechanism, e.g. a lead screw. In the control assembly 100 of the present embodiment, each actuator comprises or consists of an electrical motor 121, e.g. enclosed by a motor housing, a gear reduction unit 122, e.g. provided as a gear box, a gear transmission unit 123 and a linear actuator member 124 (e.g. actuator post or lead screw). The gear transmission unit 123 converts the rotary motion of an output shaft of the gear reduction unit 122 to the linear motion of the linear actuator member 124.

Other types of actuators, besides electromotors, may be pneumatic actuators or hydraulic actuators. Electromotors as actuators may be powered and controlled through a single wire connection, for instance by using power line modulation. This has the advantage the battery packs are not required, which tend to be bulky. The available space within a target tube is limited so that compact arrangements for powering are preferred. Moreover, battery packs have a limited cycle lifetime, which necessitates their regular replacement. A production campaign, if running, has to be stopped to perform this replacement.

In exemplary embodiments of the invention, the magnetic structure 110 is coupled to the support structure 150 via the actuators 120a-d and a circumferential outer wall of the tubular support structure 150 with end caps 151, 152 forms a protective enclosure for the magnetic structure 110. Connection pieces 126 may be provided on the radially inwards oriented face of the pole piece 113, opposite to surface of the pole piece that supports the magnet arrays 111, 112, and be configured to cooperate with corresponding head pieces 125 of the linear actuator members 124 to fasten the magnetic structure to the actuators, thereby establishing an indirect coupling between the magnetic structure and the support structure. The described way of coupling the magnetic structure and actuators to the elongate support structure guarantees that the actuators can act on the magnetic structure to change a position of the magnetic structure in several distinct locations along the length axis of the magnetic structure. However, embodiments of the present invention are not limited to this particular type of coupling, which can be performed in many ways.

In a variant of the previously described embodiment, the pole piece (e.g. soft iron pole piece) of the magnetic structure may be separated longitudinally, e.g. cut along the length direction of the support structure, so that three elongate, e.g. equally wide, pole piece segments or strips are obtained instead of a single one. The middle pole piece segment or central strip may then carry the central array of magnets 111 and the end magnets (outermost magnets) of the peripheral array of magnets 112, while the remainder of the magnets composing the peripheral array of magnets 112 is placed on the two outer pole piece segments or peripheral strips. The coupling mechanisms that connects the three pole piece segments to the support structure (e.g. directly or indirectly via the local actuators) may comprise hinges. A linear motion of the local actuator, e.g. exerting a deformation on the central pole piece segment, may in addition or selectively be translated into a variable tilting angle of the peripheral pole pieces and attached magnets. As such, the angle that is spanned between the two legs of the magnetic/plasma racetrack legs may be tuned locally towards smaller angles, by turning the outer pole pieces inwards and towards each other, thereby reducing the azimuthal distance between the magnets of the peripheral array attached to the outer pole pieces that are being rotated, or towards wider angles, by tilting the outer pole pieces outwards and away from each other, thereby increasing the azimuthal distance between the magnets of the peripheral array attached to the outer pole pieces that are being rotated.

Moreover, the fact that actuators are adapted to change the position and/or orientation of the magnetic structure locally does not exclude the possibility to tune the magnetic structure globally. A global tuning of the magnetic structure may be obtained via one or more dedicated global actuators or, preferably, by driving the local actuators in unison so that a global position change (e.g. global translation along at least one travel axis) and/or a global orientation change (e.g. global rotation about at least one orientation axis) of the magnetic structure results.

Although having been described as tubularly shaped so far, the support structure may adopt a non-tubular shape in different embodiments of the invention. For instance, the support structure may comprise a substantially planar portion as a mounting platform for the control unit, storage device and actuators, and an elongate shaft onto which the planar portion can be attached. A protective and insulating sleeve or protective and insulating material layer such as paint can be applied to the mounted parts on the support structure, e.g., the control unit, storage device the actuators, and the magnetic structure coupled to the actuators. In still other embodiments, a substantially planar mounting platform or plate may be combined with an extrusion profile or elongate pipe whose cross section has the shape of arc segment, e.g. a circular arc segment, to assemble the elongate support structure.

The control assembly according to embodiments of the invention is connectible to an end block of a magnetron sputter apparatus, e.g. comprises connection means for mounting the support structure to at least one end block. Such connection means may include an inner receiving flange or bearing member of the end block that cooperates with an end tap of the control assembly. A target may be mounted onto an outer support flange of the end block and circumferential enclose the control assembly; the target mounted to the end block may be affixed to the support structure of the control assembly via a counter center at the opposite end of the target (distant to the end block). Besides, the control assembly may be connectible to two distinct end blocks positioned at respective end portions of the support structure, e.g., via end pieces, closing caps, lids or flanges of the support structure or fastened to the support structure.

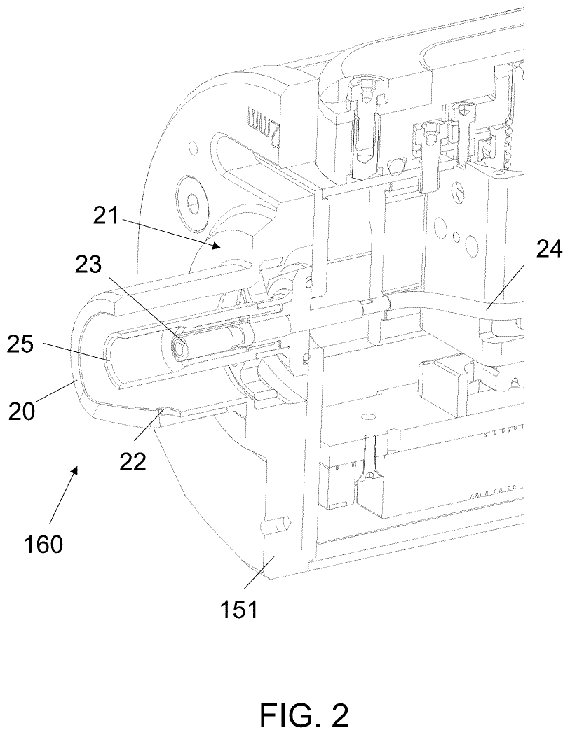

FIG. 2 is an enlarged view of a mechanical and communication interface 160 of the control assembly 100, which allows connecting the support structure 150 to an end block. A journal of the interface 160 is formed by a shell-like end tap or hollow cylindrical section 20 that projects orthogonally from a beveled region 21 on the outer face of the end piece 151. The journal may be oriented substantially coaxially with respect to the length axis, e.g. center axis, of the elongate support structure. The shell or cylindrical section 20 comprises a slot 22 for aligning the support structure and magnet bar assembly with respect to the end block, e.g., upon sliding the journal into a bearing element (e.g. bore or bushing) of the end block. The shell or cylindrical section accommodates, in its interior, an electrical pin 23 which forms part of an electrical connector between control assembly 100 and the end block. When connecting the control assembly to the end block, the electrical pin is inserted into a socket provided in the end block. Therefore, the electrical pin corresponds to the male connector part of a plug-and-socket type electrical connector. Nonetheless, the female connector part (e.g. socket) of a plug-and-socket type electrical connector may be provided in the mechanical interface is alternative embodiments of the invention. A shielding 25 around the electrical pin 23 may assist in aligning the electrical pin and, advantageously, may also comprise built-in fluid seals to shield data signals travelling across the interface 160 from surrounding coolant fluid, e.g. water.

The electrical connector may be a signal connector in a communication link between the end block and the control assembly, which allows the control unit of the control assembly to communicate and exchange data with software or hardware modules located in or beyond the end block. An electrical cable or wire 24 is provided inside the support structure 150 of the control assembly to this effect, bridging the distance between the electrical pin 23 and a transceiver module 33 of the control assembly. Additionally or alternatively, the electrical connector may be used as a conductor of an electrical power distribution system that transfers electrical power between the end block and electronic components of the control assembly. For instance, the control unit and/or actuators of the control assembly may be powered via the electrical connector. Power line communication may be implemented in the power distribution system that includes the electrical connector such that power and data signals can be combined on a single wire/conductor.

Embodiments of the invention are not limited to an electrical communication link between the control assembly and the end block to which it can be connected. Telecommunication between the electronic components of the control assembly and electronic components connected to the end block, e.g., across the mechanical interface, may be wired or wireless, e.g. telecommunication signals may be transmitted optically, acoustically, as RF-signals, via capacitive or inductive coupling. Telecommunication links may also be installed between electronic components of the control assembly and units or sensors of the magnetron sputter apparatus and/or the coating system that comprises the control assembly. A signal transmitter and/or receiver may be coupled to the elongate support structure alongside the control unit and operatively connected to the control unit, while at least one signal transmitter is arranged at a distance from the control assembly.

By way of example, an optical telecommunication link between the end block and the control assembly (e.g. magnet bar assembly) may comprise a fiber optical cable and fiber optical connectors, or an optical signal emitter arranged in or near an end block in combination with an optical receiver in the control assembly. Optical signals may at least partly be propagated in a liquid waveguide that is formed by coolant liquid flowing along fluid channels inside the support structure or flowing in a space between the outer wall of the support structure and an inner wall of the target tube in a magnetron sputter apparatus. Optical windows may be provided in either or both of the end pieces of the support structure.

FIG. 3 is a detailed view of the part of the control assembly 100 where the control unit 130 is situated. The storage device 140 is placed nearby the control unit 130, e.g. by mounting the storage device and the control unit onto the same circuit board 31 or onto neighboring circuit boards, and is operatively connected to the control unit 130 so that the control unit can access data that is stored in the storage device 140. Electrical wires or signal traces of a printed circuit board may be provided to this effect. Installed proximately to each actuator of the assembly, driver circuits 127 are configured to covert control signals into corresponding drive signals. The drive signals are suitable for driving the electromotor 121 of the respective actuator in a controlled fashion. Each driver circuit 127 thus acts as a local motor controller. Control signals are generated and output by the control unit 130 and are sent over interface wires 34 to respective interface connectors 35 of the driver circuits 127 (for reasons of visibility an actuator in front of interface wires 34 and interface connector 35 has not been drawn in FIG. 3). In embodiments of the invention, control signals and drive signals are different type of signals. Drive signals, e.g. PWM signals, are generated by the driver circuits in response to a control signal and force the actuator, e.g. the linear actuator member, to change its current position and/or orientation in accordance with the drive signal. The drive signal is therefore used to set the new position and/or orientation of the actuator. A feedback loop, e.g. measurement of the current actuator position/orientation and comparison to the target position/orientation to derive a correction signal, may be implemented for this purpose. In contrast to the drive signal, the control signal is merely used to convey information on the desired new actuator position/orientation to the driver circuit. The control signal may encode the value of the new actuator position/orientation according to a communication protocol or to optimize the transmission of data packages exchanged between components of the same control assembly. Control signals are thus designed to perform tasks that are inherent to a transport layer in addition to the transmission of control data pertaining to the setting of the actuators. These tasks may comprise driver circuit addressing, data encoding, timing of data frame transmissions, optimizing transmission over the particular interface wires, implementation of a particular communication protocol, handshaking operations, fault or timeout detection, frame retransmission after fault or timeout detection, implementation of forward error correction schemes, and the like. Decoupling the control and the driving by performing these tasks in different units has the advantage that the driver circuits can be designed or provided as more compact, less complex and cheaper circuits. Moreover, the exchange of external data can be managed exclusively and more efficiently by the control unit, which mitigates data traffic at low speeds across the communication link through the mechanical interface. In particular, setpoints for the actuators are determined or computed by the control unit in accordance with prestored inputs residing in the storage device, which can be accessed quickly even for a large number of actuators and corresponding control points of the magnetic structure. Control trajectories do not have to be computed remotely and sent across the communication link any longer, as this task is performed by the control unit within the magnet bar assembly. This enables faster tuning of the position and/or orientation of the magnetic structure. As a result, the control assembly can quickly adapt the magnetic structure of a magnetron to changes in the sputtering process, e.g. online adjustment of the magnet bar in a magnetron sputter apparatus is feasible. Thanks to the online adjustment of the magnetic structure of the magnetron, non-flat substrates, e.g. substrates that are curved in one or two dimensions, can be coated uniformly over the entire substrate surface during a continuous coating process, despite the varying target-to-substrate surface distance for substrates moving past the sputter source of the inline coating equipment. Here, uniform coating refers to the application of a coating layer onto a surface or surface portion of a substrate material such that a layer property of the coating layer is uniform across the coated substrate surface or surface portion. The aforementioned layer properties include coating layer thickness, optical layer properties (e.g. uniform refractive index, reflectance coefficient, extinction coefficient, etc., across the coated substrate), electrical layer properties (e.g. uniform sheet resistance, etc., across the substrate), magnetic layer properties (e.g. uniform magnetoresistance or magnetic tunnel resistance, etc., across the substrate), mechanical layer properties (e.g. uniform roughness, hardness, stress, elasticity, etc., across the substrate), or morphological layer properties (e.g. uniform crystal structure, crystal orientation, density, etc., across the substrate).

External data reaches an input connector 32 of the control unit 130. Here, external data refers to data in general, including commands, settings, updates, and measurements, which is prepared (e.g. gathered, created, . . . ) remotely, i.e. at a distance from the control assembly, and transmitted to components of the control assembly via a dedicated communication link. The external data stems from external sources such as trigger units, sensor units, hardware or software modules, which do not form part of the control assembly but communicate with components of the control assembly—mainly the control unit—via the dedicated communication link. The input connector of the control unit thus is operatively connectible to a trigger unit that is disposed distantly to the control assembly. In the present embodiment, the dedicated communication link includes the electrical connector that extends through the mechanical interface and a transceiver module 33. In other embodiments of the invention, the communication link may not be electrical, e.g. an optical or acoustic link, and/or be may implemented in a different way, e.g. not fed through the mechanical interface but through a signal window instead.

The transmitter and/or receiver module 33 is an optional component of the control assembly that is not needed in all the embodiments of the invention. It may be adapted according to the physical signal type used for communication, e.g., transceiver module for electrical signals, antenna and transmitter/receiver module for wireless signal, optocouplers or photoreceiver module for optical signals, etc. It has the advantage, however, of allowing the conversion of a signal type (e.g. optical to electrical or vice versa), signal level (e.g. voltage amplitude level) and signal transmission format (e.g. digital or analog transmission formats or protocols) according to the characteristics of the particular communication link and the I/O capabilities of the electronic components inside the control/magnet bar assembly. Data signal conversion by means of module 33 may be helpful if the control unit is not capable of safely receiving or interpreting the raw data signals that are used for transmission across the communication link 160. Furthermore, it may often be beneficial to transmit data only in a pre-determined low-frequency band to reduce the risk of erroneous data signals being transmitted through the communication link in the presence of higher-frequency noise, whereas higher-frequency signals may be used for communication between the components of the control assembly that are easier to shield from noise. Noise interferences that perturb data transmission through the mechanical interface may originate in the electrical power signals that are supplied to the sputter target, arcing events, or plasma ringing effects, but are not limited thereto. This limits the available bandwidth and speed for external data exchange across the communication link. Hence, the amount of and the frequency at which the external data is exchanged and consumed by control unit should be reduced as much as possible. In conventional magneton systems, transmitting control commands for all the actuators across the communication link between the magnet bar assembly and the thereto connected end block and regulating the actuators to their new desired positions can last for many seconds: this is too long compared to the time it takes for substrates to be transported past the sputter source. Moreover, variable settings are often required during this exposure time.

The storage device preferably comprises a persistent memory, e.g. an integrated circuit flash memory or other type of non-volatile memory, such that the data stored therein is not lost if the storage device is unpowered. This minimizes energy consumption and latency due to relocating/rewriting the data to be stored into the storage device before it is accessible to the control unit during the sputter process. Alternatively, a non-persistent, e.g. volatile memory can be used as the storage device and the relevant data can be loaded into the storage device at the start of a specific production campaign, or uploaded on a change of a substrate type. The data that is stored on the storage device relates to control inputs for the control unit, i.e. inputs that are required by the control unit to determine control trajectories for the respective actuators and translate the control trajectories into a sequence of control signals that can be validated and interpreted by the driver circuits for the respective actuators. Additionally, one or more sputter process parameters, sputter recipes, magnetron sputter apparatus configuration parameters, and/or substrate surface related information may be stored permanently in the storage device and be accessed by the control unit to compute a transformation of the setpoint lists. It is advantageous to store only a limited number of approximate setpoint lists on the storage device, which can then be adapted, transformed or manipulated by the control unit to obtain a multitude of improved setpoint lists, each being more accurate in view of a specific sputter process, magnetron apparatus configuration, or substrate surface property.

In embodiments of the invention, the control assembly comprises at least one control unit which is configured to:
load control inputs from at least one storage device;
determine a control trajectory for at least one actuator based on the control inputs;
generate a sequence of control signals for the at least one actuator in accordance with the control trajectory; and
synchronize the transmission of the sequence of control signals to a driver circuit of the at least one actuator with a trigger signal from a remote trigger unit, external to the control assembly.

The control inputs comprise a setpoint or setpoints for the at least one actuator or, alternatively, data which allows the calculation of one or more setpoints for the at least one actuator. A control trajectory in its simplest form contains a list of at least one, but must often multiple regulated positions of the actuator. Here, a regulated position may be identical to a setpoint, or may be derived from a setpoint. For instance, the control unit may be configured to perform a calibration step on the loaded setpoints when determining the regulated positions of the control trajectories. This allows the correction of actuator offsets and/or the compensation of drifts, sensitivity changes or actuator misalignments due to ageing, temperature, wear, etc. The values needed for the calibration step can be stored on the storage device too. Preferably, setpoints for the actuators are stored as lists or tables on the storage device(s) so that setpoints of a particular actuator can be easily retrieved. List or table headers may contain information that allows the identification of each actuator and its corresponding setpoints and, optionally, any available input for calibration.

There may be many different lists or tables stored on the storage device, each containing the actuator setpoints for a particular control or tuning scenario for the magnetic structure. Tuning scenarios can be pre-defined or user-defined scenarios which can be written into the storage device at various moments: directly after manufacture, while building the control assembly, via a software client or REST-API installed on the control unit, etc. Each scenario may be characterized by a set of parameters, including process parameters like partial gas pressures, the composition and/or distribution of plasma and reaction gas mixtures, sputter mode (DC/AC/RF), parameters related to the target material, target thickness and target lifetime (e.g. kWh lifetime), parameters related to the sputter geometry (e.g. shield geometry and opening, minimum target-to-substrate distance, target length, anode position) and parameters related to the substrate (substrate material, substrate surface dimensions, substrate curvature). A unique scenario identifier can be assigned or computed from each parameter combination that characterizes the scenario. The control unit may use the unique scenario identifier to decide which list or table of setpoints to load at runtime. In some embodiments of the invention, the scenario identifier may be a user input or system input of the coater equipment that is sent over the communication link to the control unit. A software client or application programming interface (API) installed on the control unit can set a pointer to a memory location in the storage device according to the new scenario identifier. Alternatively, the scenario identifier may be communicated as part of the trigger signal that the external trigger unit dispatches to synchronize the transmission of control signals from the control unit towards the driver circuits of the actuators.

Furthermore, it is possible to add new scenarios or modify existing scenarios. The earlier is useful during the development of a new sputter coating process or production campaign, whereas the latter is useful for updating calibration routines for the actuators or correcting for slow changes in the magnetic field configuration at the target surface due to target erosion, contamination of the sputter source, and the like. Scenarios can even be swapped or dynamically updated during runtime, which greatly assists operators in tuning in the process and layer thickness uniformity profile at the start of a production campaign, or upon changing the product (different layer stack or different substrate) during a production campaign. This significantly shortens the time it takes to set up the inline coating equipment before the start of a new production campaign or when changing the product during a production campaign and the time-consuming of repeated venting steps of vacuum deposition chambers can be avoided.

For an actuator with several degrees of freedom, e.g. different rotation axes and/or translation axes, each list entry defines the desired value for each controlled axis of the actuator. A flat substrate to be coated with a layer of uniform thickness, for example, may require only a single entry into the list of regulated positions for each actuator. This list entry generally depends on the location of the actuator along the length axis of the elongate support structure, corresponding to a location of the actuator along the length axis of the magnetic structure. It may depend on additional factors such as target lifetime, target material, plasma composition, etc. Conversely, non-flat substrates, e.g. substrates having a curved surface or a non-constant height profile, typically require the definition of a large number of list entries. For instance, target positions may be defined for each vertex, edge or simplex/polytope of a mesh overlay for the substrate surface, resulting in a 2D-array of target positions, and a list of regulation positions may be obtained for each actuator as a selection of individual rows of the 2D-array. Nonetheless, the control unit may be configured to insert additional regulation positions when determining the control trajectories, e.g. via interpolation between the initial regulation positions. This may assist the driver circuit in moving the actuator in a smoother and less rugged fashion, avoiding overshoot or ringing, avoiding extreme accelerations, etc.

In some embodiments of the invention, the control unit may be configured to load setpoints for the actuators of the control assembly from one or more memory locations of the storage device and apply a transformation to the loaded setpoints. A transformation function may be applied pointwise with respect to each loaded setpoint. Preferably, a simple transformation function, e.g. a linear function, is evaluated by the control unit, as it is easy to compute and does not need a lot of processing power. The applied transformation function may be stored in the storage device, e.g. as part of an executable code or run-time library that can be accessed by the control unit, or can be communicated to the control unit via the communication link. Any transformation function that is applied to the setpoints may accept further parameters as inputs. This allows the transformation function to take into account additional process or equipment parameters, e.g., the transformation function may represent heuristic or previously measured relationships between the loaded setpoints and the transformed setpoints under a given change of a process or equipment parameters.

By way of example, the loaded setpoints for the actuators may be associated with a particular process, e.g. a tungsten sputter process, whereas the control unit has received external data, e.g. through the trigger signal, which defines a different process, e.g. an aluminum sputter process. The control unit may then apply a scaling transformation to the loaded setpoints, in which the scale factor plays the role of the further input parameter that describes the quantitative change in the setpoints when aluminum replaces tungsten as the target material to be sputtered. In this specific case and depending on, e.g., the working pressure of the sputter process, the expected deposition material distribution may alter significantly. In the case of a relatively high working pressure, the sputtered material particles may undergo many interactions and collisions with the working gas. In the case that the working gas comprises, e.g., argon, nitrogen or oxygen molecules, the scattering of the sputtered particles may be different. Aluminum is a rather small and light atom and may deviate its movement path significantly after gas interaction, while the heavy tungsten atom will be much less affected in its trajectory by a similar gas interaction.

Alternatively or additionally, the loaded setpoints for the actuators may be associated with a particular lifetime of the target material to be sputtered, e.g. zero lifetime of the target when mounted for the first time, whereas the control unit has received external data, e.g. through the trigger signal, which defines a different lifetime of the sputter target, e.g. a specific amount of kWh for a sputter target that is currently in use and has already undergone erosion. The control unit may then apply an alternative or additional scaling transformation to the loaded or already transformed setpoints, in which the scale factor plays the role of the further input parameter that describes the quantitative change in the setpoints when a sputter target is in use that has a non-zero lifetime. Embodiments of the invention are not limited to the preceding transformations or to simple scaling functions, but may use different input parameters and/or more complex functional relationships instead. This includes the use of transformation tables (e.g. look-up tables) or the application of transformation functions as part of a feedback control algorithm that can be executed by the control unit. A transformation of the loaded setpoints is equivalent to an adjustment of the control trajectories for the actuators in embodiments of the invention in which the loaded setpoints are directly used as regulated positions. In other embodiments of the invention, the loaded setpoints may be altered into regulated positions after loading by the control unit to allow generation of the control trajectories, for instance when performing calibration or feedback control. In these cases, the transformation can be similarly applied to the regulated positions of the generated control trajectories to obtain adjusted control trajectories.

In some embodiments of the invention, the control inputs loaded from the storage device into the control unit are distinct from setpoints for the actuators, but allow the calculation thereof. In such embodiments, the control unit is additionally configured to derive the setpoints for the actuators of the control assembly based on the accessed control inputs. Although computationally more intensive, the computation of the setpoints by the control unit, or another processing unit of the control assembly managed through the control unit, improves flexibility and ease of use by the end users when preparing and writing or rewriting the kind of control inputs into the storage device so that can be accessed by the control unit. One example is the prescription of the local sputter rate for each point on a computational grid that overlays the curved or non-curved substrate surface to be coated uniformly or in accordance with a predetermined coating profile. As the substrate moves past the sputter source, the local sputter rate needs to be adapted dynamically, which is solved wholly or at least partially by a corresponding adaptation of the regulated positions of the actuators along the support structure of the control assembly. The control unit, or a further processing unit of the control assembly managed through the control unit, may then compute the actuator setpoints as a function of the prescribed local sputter rates at each grid point. Additional information with regard to the current sputter process and equipment, if required to perform the computation of the setpoints or to improve the computation of the setpoints, may be accessed on the storage device or received as external data that is communicated to the control unit via the communication link. Another example is the prescription of the substrate height for each point on a computational grid that overlays the curved or non-curved substrate surface to be coated uniformly or in accordance with a predetermined coating profile. As the substrate moves past the sputter source, the distance between the sputter source and the substrate surface to be coated varies dynamically and requires the local sputter rate to change accordingly. This can be solved wholly or at least partially by a corresponding adaptation of the regulated positions of the actuators along the support structure of the control assembly. The control unit, or a further processing unit of the control assembly managed through the control unit, may then compute the actuator setpoints as a function of the prescribed substrate surface height at each grid point. Substrate surface heights at various points of a computational grid may be included or extracted from a CAD profile or measured surface scan (e.g. optical or mechanical surface scan), which can be written into the storage device. Advantageously, the control unit or processing unit managed thereby computes the setpoints once for each new sputter process, change in product (e.g. different coating layer property), and/or change in substrate (e.g. different surface profile) and stores the computed setpoints in the storage device so that they can be readily accessed by the control unit when sputter-coating similar substrates in a similar sputter process. Moreover, computation of setpoints for a new sputter process, change in product, and/or change in substrate may be performed ahead in time, while the current process, product, and/or substrate type is still continuing. Computed setpoints can be exported so that an operator or process engineer is permanently informed over the current and future configurations of the actuators in the control assembly. This allows a smooth and fast adaptation of a magnetron sputter apparatus to the changing process, product, and/or substrate without interruption of a running production campaign. A downtime of the magnetron sputter apparatus and associated coating line can thus be reduced and operational costs be saved. Likewise, the time required for developing a new sputter coating process or tuning in of the magnetron sputter apparatus and associated coating line at the start of a production campaign can be significantly reduced.

In particular embodiments of the invention, the control unit may be equipped with additional local processing power, e.g. the control unit may comprise a co-processor as a subunit. This allows the control unit to transfer computational tasks to the co-processor, where they are performed more efficiently. The computational tasks may include the application of transformation functions on the actuator setpoints or regulated positions, or the online computation of the setpoints based on the information loaded from the storage device such as setpoint calculation from substrate height profiles or CAD files.

The regulated positions of the actuators appearing in the control trajectories are translated into corresponding sequences of control signals, e.g. by encoding them and placing them into a data frame of a prescribed communication protocol. This translation may be performed sequentially, e.g. each new control signal of the sequence being generated once the preceding control signal of the same sequence has been sent, or they are all generated in one step prior to sending out the first control signal. Each sequence of control signals addresses a corresponding one of the driver circuits and the individual control signals of this sequence are dispatched consecutively.

The duration of the time intervals between the dispatch events of two consecutive control signals in the sequence may be determined by the control unit based on substrate transport profiles, which can be stored on the storage device and accessed by the control unit, or can be communicated as external data to the control unit via the communication link. The substrate transport profile are precomputed lists or tables that define the time intervals between consecutive control signals for a given substrate movement trajectory past the sputter source and a given mesh/grid over the substrate surface that is allocating the reference points on the substrate surface for which target positions of the actuators are defined. Alternatively, the control unit may access a constant value for the time interval between the dispatch events of two consecutive control signals in the sequence from a memory location in the storage device, or such constant value is transmitted to the control unit via the communication link, e.g. may be contained in the trigger signal that the control unit detects on its trigger input signal connector.

The control unit in accordance with embodiments of the invention is configured to synchronize the transmission of the control signal sequences with a with a trigger signal at its input connector. The trigger signal is issued by an external trigger unit that is arranged at a distance to the control assembly and is communicated to the control unit of the control assembly via the communication link across the mechanical interface or via a separate communication link. In practice, the trigger signal will be directly or indirectly related to the position of the substrate to be coated relative to the magnetic structure whose position/orientation is adjusted by the actuators of the control assembly. This enables the control unit to determine a start time for the transmission of the control signals in each sequence of control signals. In some embodiments of the invention, the control unit may commence transmitting the first control signal of at least one sequence of control signals, e.g. all sequences, immediately upon reception of the trigger signal at its input connector. In other embodiments of the invention, the control unit may compute a respective start time or delay for transmitting the first control signal of each sequence based on the trigger signal received at its input connector. This computation of the start time or delay may use the time attributed to the trigger signal detection event at the input connector of the control unit, additional information regarding the sending trigger unit, e.g. identifier allowing the extraction of the trigger unit's position in the coater equipment relative to the magnetic structure or accessing the trigger unit's position in a table stored on the storage device, which is part of the trigger signal, and substrate transport speed information that is either contained in the trigger signal or accessible on the storage device.

The external trigger unit may be a sensor unit of the inline coating equipment. An exemplary sensor unit is a substrate position sensor that detects moving substrates in a location along the substrate's trajectory through a vacuum deposition chamber. Such a position sensor may be placed along the conveyor system which transports the substrate through the chamber and be configured to emit a trigger pulse upon detection of the substrate in the sensed location. The trigger pulse can thus be transmitted to the control unit to synchronize the timing of the control signals in the sequences with the substrate position.

In embodiments of the invention, a plurality of these sensor units may be placed along the conveyor system, thereby allowing the detection of the substrate in different sensed locations while moving through the deposition chamber and past the sputter source. A corresponding plurality of trigger signals can thus be obtained and transmitted to the control unit to improve and/or maintain a good synchronization of the timing of the transmitted control signals with the substrate position relative to the magnetic structure whose position/orientation is being controlled.

In embodiments of the invention, a trigger signal may have different degrees of complexity. For instance, the trigger signal may correspond to at least one interrupt request (e.g. single pulse) or may encompass a signal train with a prescribed format of data (e.g. containing the substrate type, movement speed, or e.g. substrate position).

In yet other embodiments of the invention, the trigger unit may be part of the coater equipment or substrate transport system, e.g., movable parts thereof whose motion is correlated to the substrate position in the coating equipment. For instance, the trigger unit may correspond to the entrance valve that separates the vacuum deposition chamber containing the control assembly from a load lock section or another deposition chamber along a coating line. When the gate has reached its opened state, a trigger signal may be released and transmitted to the control unit. The time required for a substrate of predetermined size to pass the gate and travel until a position under the sputter source that contains the control assembly may be stored on the storage device and be accessible to the control unit, or may be encoded into the trigger signal itself. Likewise, the trigger signal may correspond to a homing position signal that is generated as soon as the exit valve opens to let the coated substrate leave the deposition chamber. Embodiments of the invention are not limited to the trigger units described hereinabove and other components of a sputter magnetron apparatus may act as trigger unit.

In embodiments of the invention in which the control unit determines the intervals between subsequent control signals, a timing subunit of the control unit or a timing unit of the control assembly, e.g., an incremental counter, may provide a timing signal as reference of comparison when determining the moment in time the interval between subsequent control signals has elapsed. The timing subunit of the control unit or the timing unit of the control assembly may include a clock signal generator or oscillator. Alternatively, subsequent trigger pulses may be used to time the transmission events of subsequent control signals.

More than one storage device and/or more than one control unit may be comprised by the control assembly in embodiments of the invention. For instance, different setpoint lists or tables may be stored in different storage devices that form a distributed shared memory with respect to one or more control units. The different lists of setpoints may be associated with different process parameters that influence the sputter coating process. In particular embodiments, the control unit is thus capable of quickly responding to a change in the sputter process conditions (e.g. change of partial gas pressure, change of electrical power supply to the target, change in target or substrate surface temperature, etc.) by switching from a first list of setpoints stored in a first storage device to a second list of setpoints stored in a second storage device. Alternatively, the different lists of setpoints may be stored and indexed as separate tables in the same storage device, provided the storage device has sufficient memory size.

According to some embodiments of the invention, the control assembly comprises a plurality of actuators and a corresponding plurality of control units. Each control unit may access its own storage device. This allows parallel and independent control of a large number of actuators spread over the length of the control/magnet bar assembly, without having to worry about memory congestion and implement complex time-multiplexing data processing and signaling schemes.

In another aspect, the present invention relates to a magnetron sputter apparatus comprising the control assembly of the first aspect, a magnetic structure attached to the support structure of the control assembly, a sputter target mounted substantially coaxially over the support structure, and an end block system connected to the assembly and the sputter target. The magnetron sputter apparatus may further comprise at least one trigger unit that is external to the control assembly and arranged distantly to the control assembly. The at least one trigger unit may be a substrate position sensor. The magnetron sputter apparatus is suitable for sputter-coating of a non-flat substrate by a coating layer having a uniform layer property across the substrate surface to be coated. The magnetron sputter apparatus is suitable for sputter-coating non-uniform coating layers onto flat or curved substrate surfaces, wherein the non-uniform coating layers are controllable and specified by a coating layer profile.

In embodiments of this aspect of the invention, the sputter target is a rotary target. It is generally shaped as an elongated hollow body of revolution, which can have differently shaped inner and outer surfaces extending along the axis of elongation. In some embodiments of the invention, the sputter target has a cylindrical or nearly cylindrical outer surface of revolution, thus generating a tubular sputter target. For instance, the inner and outer surface of revolution are separated by a fixed distance in the radial direction, perpendicular to the axis of revolution, resulting in a hollow cylinder with fixed inner and outer diameter. Another example is that of cylindrical inner surface with fixed inner diameter (i.e. generated by revolving a straight line parallel to the axis of revolution) and an outer surface of revolution of the sputter target that has a varying outer diameter, e.g. an outer diameter that is constant in a central portion of the sputter target but widens towards or at the end portions of the sputter target. Outer surfaces of revolution in the shape of a dog bone or a dumbbell are examples of outer surfaces that have a varying outer diameter. Advantageously, such widened end portions of the sputter target partially or completely offset an increase in the target erosion (end grooving) that is mainly due to the turnaround sections of the plasma racetrack (change in plasma density and longer dwell times of target material under plasma bombardment) adjacent to these end portions under sputtering conditions. The widened sections of the target may be the result of a thicker sputter material inventory in these sections, which is applied to a cylindrical outer diameter backing tube, or the result of a shaped backing tube, e.g. a backing tube comprising non-consumable collars welded onto sections for which the widening is desired, e.g. end sections of an otherwise straight backing tube. The sputter material thickness may be uniform on shaped backing tubes, or may have a variable thickness (but constant outer diameter, for instance).

In yet another aspect, the present invention relates to an inline vacuum sputter coating apparatus comprising the magnetron sputter apparatus of the previous aspect of the invention, a transport system for moving the substrates past the magnetron sputter apparatus, and at least one trigger unit external to the control assembly of the magnetron sputter apparatus and arranged distantly to the control assembly of the magnetron sputter apparatus.

Typically, the inline coating apparatus comprises a vacuum chamber with an entrance and exit slits through which the substrate to be coated continuously enter and leave the deposition chamber, respectively. The entrance and exit slits may comprise gate valves that connect the deposition chamber to load locks, purge chambers or further deposition chambers along the coating line of the sputter apparatus. A transport means such as rollers or a conveyor belt transports the substrates to be coated through the deposition chamber and past the sputter source. During transport, the substrates to be coated may be secured to substrate holders or frames. The inline coater apparatus may be configured as a horizontal or vertical coater. In the horizontal design, the substrate surfaces to be coated are oriented parallelly to the floor and perpendicularly to the direction of gravity, whereas the substrate surfaces to be coated are oriented substantially perpendicularly to the floor in the vertical design. The sputter source typically comprises an end block that is mounted onto the wall of the vacuum chamber (e.g. side mount or drop-in) and has an interface with external and non-vacuum parts of the sputter apparatus. In particular, the interface provides a feedthrough for a coolant, an electrical feedthrough and, optionally, a drive means system (for target rotation mainly, but possibly also for magnet structure tilting), a communication channel for sensor, trigger and control data, and others. Transmission structures of mechanical movement, which independently transmit the driving motion (e.g. driving force, torque) of external drive means to a target support member of the magnetron sputter apparatus, may also be arranged in the end block and partly in the interface. A coolant—typically water—is generally needed to remove heat from the target, e.g. being tubular, and the inner components of the magnetron assembly, which is generated during sputtering, whereas electrical power needs to be supplied to the target. The end block also provides electrical insulation means for protecting sensitive electronics and accessible parts of the magnetron housing from the high-power electrical signal that is applied to the target during sputtering, as well as sealing cassettes for liquid sealing of the coolant circuit and vacuum sealing, which prevent liquid and gaseous leaks, outgassing into and contamination of the deposition chamber.

The at least one trigger unit may be a sensor unit comprising one or more position sensors for detecting the substrates in a predetermined location along the transport system, or may be a detector unit for detecting the position or opening state of a vacuum valve, e.g., an entrance or exit valve of a deposition chamber of the inline sputter coating apparatus in which the control assembly is mounted. The at least one trigger unit is configured to transmit a trigger signal to the at least one control unit when individual ones of the substrates are detected in predetermined locations along the transport system. An inline vacuum sputter coating apparatus of this kind is suitable for generating repetitive and reproducible coating profiles on moving substrates.

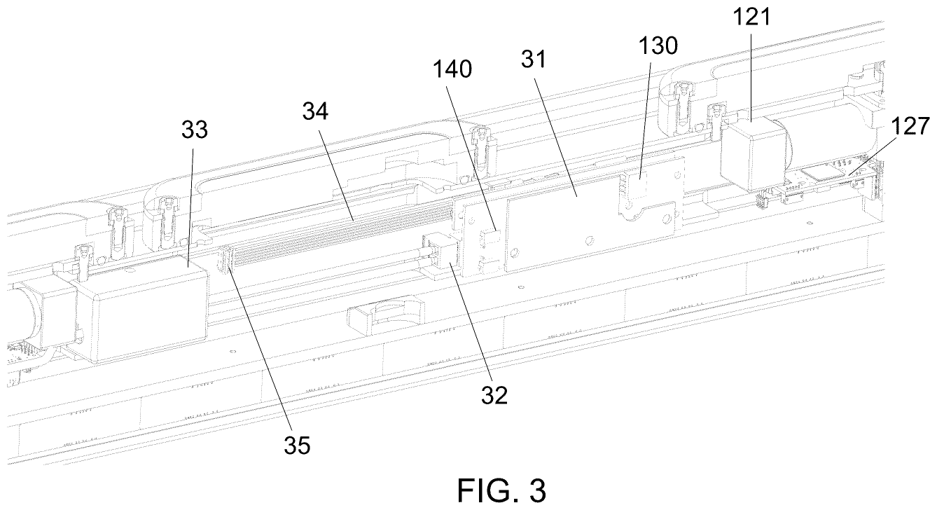

FIG. 4 is a cross-sectional view of a vacuum deposition chamber 400 with magnetron sputter apparatus as parts of an inline vacuum sputter coating apparatus in accordance with embodiments of the invention. The magnetron sputter apparatus comprises a control assembly 100 according to the first aspect of the invention, a magnetic structure 111 attached to the support structure 150 of the control assembly 100, a sputter target 436 mounted substantially coaxially over the support structure 150, and an end block system 438 connected to a distal end of the control assembly 100 and the sputter target 436. A proximal end of the control assembly and sputter target may be freely suspended in the deposition chamber or may be connected to another end block.

The sputter target 436 is rotationally supported by the end block system 438, e.g. on a rotatable mounting flange onto which the sputter target can be clamped, and has a rotation axis ‘R’ that is substantially coaxial with the length axis of the control assembly, e.g. the length axis of the support structure 150. In other embodiments of the invention, the rotation axes of the first and second support member may be parallel but offset with respect to each other. Moreover, the sputter target 436 is rotatable relative to the control assembly 100 and in particular relative to the magnetic structure 111 coupled to the control assembly. The control unit 130 of the control assembly is coupled to an interior wall of the support structure 150 and is operatively connected to a storage device (not shown). Although shown as a hollow cylindrical tube, the support structure may comprise parts or surface portions that have a substantially planar mounting surface, e.g., a hollow support tube that that has the cross-section of a half circle. Another exemplary support structure that is defining a reference plane comprises a bent sheet metal, an extrusion profile, or a combination of both.

End block 438 is mounted onto a wall of a vacuum chamber 431 and a drive means (not shown) for the target support member, e.g. motor-belt or motor-gear systems or direct drive system, may be compactly arranged inside the end block 238 or provided in a drive box that is attached to the deposition chamber wall. In the latter case, mechanical movement transmission structures or components that adequately transmit the generated driving motion (e.g. driving force, torque) are provided and extend through the interface of the end block, which may also contain feedthroughs for the coolant and the electrical power signal. Alternatively, the coolant, electrical feedthrough and/or drive means for the target support member are arranged in an opposite, second end block. Mechanical movement transmitting structures may include a drive shaft or spindle onto which a flange or disk is mounted as target support member. Alternatively, an end portion of the drive shaft or spindle may be adapted to receive and support the target directly.

A magnetic structure 111 is typically formed by opposite magnetic poles arranged to induce a magnetic field in front of a target surface. In longitudinal magnetron systems, the central portion may consist of three rows of magnets, e.g. three magnet arrays or magnet tracks. Magnets of the central row have associated magnetic poles of a first magnetic polarity in the vicinity of the surrounding target 436 and magnets of the two peripheral or side rows have associated magnetic poles of a second magnetic polarity, opposite to the first magnetic polarity, in the vicinity of the surrounding target 436. The magnets of the central row and/or the peripheral rows may have a profiled top shape, or may be slightly inclined relative to each other, so that they better conform to the circular inner surface of the target 436. A protective sleeve or housing (not shown) may be arranged circumferentially around the magnetic structure 111, between the magnet rows of the magnetic structure and the target, to avoid corrosion of the magnetic structure by the cooling fluid, e.g. water. A plasma racetrack or plasma tunnel 441 is induced by the magnetic structure 111 under sputtering conditions of the magnetron sputter apparatus, i.e., in conjunction with an electrical power signal that is supplied to the mounted sputter target 436.

The magnetic structure 111 is coupled to support structure 150 via corresponding actuators 120, completing the magnet bar assembly. The actuators 120 may contact the magnetic structure or segments of the magnetic structure directly and enable the translation of the magnets along a radial direction, perpendicular to the rotation axis ‘R’, and optionally also the rotation of the magnets about an axis parallel to the rotation axis ‘R’ and/or about an axis perpendicular to the rotation axis ‘R’. Alternatively, actuators may be connected at different axial tuning positions to the back side of an elongate magnetic pole piece, while a front side of the same magnetic pole piece serves as an attachment surface for the radially inwards oriented end faces of the magnets that are arranged along the different rows of the magnetic structure. A translational and/or rotational displacement of each actuator locally exerts a bending or torsion force on the pole piece which brings about the desired adjustment of the position and/or orientation of the magnetic structure. The magnetic pole piece may be segmented or cut along, across or diagonally relative to its length for facilitating translational and/or rotational displacement towards a desired direction, while reducing the required exerted force on the magnetic structure.

Substrates 435 to be coated enter and exit the deposition chamber 431 through corresponding slits 432, 433. A conveyor belt 434 transports each substrate 435 across the chamber 431 and past the sputtering source. As indicated, the substrate 435 may have a height profile, a sloping surface, or a curved surface to be coated in a direction of substrate transport ‘X’, which leads to varying minimum distance between the target 436 and points on the substrate surface to be coated. In addition, the substrate surface may have a height profile or surface curvature in the direction of axis ‘R’. In order to obtain a uniform coating thickness across the substrate surface to be coated, the sputter flux reaching the substrate surface has to be modulated dynamically as a function of the substrate position relative to the sputter target. Again, the sputter flux may also be varied along the direction of the common rotation axis ‘R’ to account for curved and/or profiled substrate surfaces. More generally, a desired material flux can be determined in respect of each point on the substrate surface to be coated, or in respect of each cell of a mesh generated with respect to the substrate surfaces, which comprises a plurality of cells. Preferably, the precise substrate surface to be coated is known beforehand, e.g. determined through distance or surface scanning measurements (e.g. optical ranging or time-of-flight) performed outside or inside the vacuum chamber (e.g. in a load-lock section), or extracted from CAD files.

As explained before, the setpoints for the actuators can be stored as lists or table entries in the storage device, or may be derived by the control unit from the previously acquired surface scans or CAD files. During operation of the apparatus, the control unit determines control trajectories for each actuator, based on setpoints that are accessed in the storage device or computed from substrate surface related information that is stored in the storage device. The control trajectories define the sequence of regulation positions for each actuator as the different surface portions (e.g. cells or points of the grid/mesh overlaying the substrate surface) of the substrate pass underneath the sputter source. The control unit transmits the control signals associated with the control trajectories in synchronization with the substrate movement across the deposition chamber. Therefore, driver circuits are capable to correctly move each actuator to the desired regulation position that corresponds to the surface portions (e.g. cells or points of the grid/mesh overlaying the substrate surface) that is currently located directly under the sputter target. Here, being located directly under the sputter target means intersecting of the sputter target material flux vector with the substrate surface.

The actual positions adopted by the actuators driven according to the transmitted control signals closely follow, and ideally match, the regulation positions along the control trajectories as determined by the control unit. Advantageously, sensor information, e.g. information related to substrate position in the deposition chamber, process parameters such as partial gas pressures, target temperature, electrical power supplied to the target, magnetic field strength along plasma racetrack, and the like is communicated to the control unit to achieve, e.g. closed-loop, feedback control, detect potential malfunctioning and/or critical operating conditions of the sputtering apparatus 400. Furthermore, metrology tools (e.g. optical measurements, such as spectral transmittance and/or reflectance data) measuring the coating performance inside or outside of the coating equipment may provide mapping data of layer performance across the substrate and can be used to implement feedback control through the control unit. A feedback control loop is executed by the control unit which receives the additional sensor data as feedback input data and re-adjusts or updates the control trajectories for the actuators quasi instantaneously. The regulation positions for the actuators may be corrected based on a comparison between the desired actuator positions and detected deviations in the received sensor data. Alternatively or additionally, the control unit may send control signals to the conveyor 434 in order to correct a position and/or transport speed of the substrate. Deviations from the desired values of the regulation positions may be caused by irregularities in the substrate movement during transport, irregularities in the target erosion profile, minor sample to sample variations of the surface shape of the substrate, etc.

The control unit achieves synchronization of the transmitted control signals with the substrate position relative to the control assembly and sputter target through the detection of one or more trigger signals at its input connector(s). The trigger signals convey substrate position information or events in the process that are related to a specific position of the substrate in the deposition chamber to the control unit, which enables the control unit to time the transmission event of each control signal accurately. Trigger signals that can be communicated to the control unit 130 for the purpose of achieving synchronization include event-driven data such as a substrate 435 entering or leaving the chamber 431 via the entrance slit 432 or the exit slit 433, respectively, and/or substrate position data detected by position sensor 440a-c arranged along the conveyor 434.

In variants of the described magnetron sputter apparatus, multiple similar sputter targets and magnet bar assemblies, e.g. at least two similar sputter sources, are mounted along the coating line in the same deposition chamber. This has the additional advantage of reducing the amount of material that is lost by sputtering onto shields. Instead, multiple sputter sources mutually sputter and receive the target material onto each other. The control unit of each sputter source may be programmed to orchestrate the synchronization of the substrate movement through the deposition chamber with the transmission of the control signals. Furthermore, measurements may be carried out behind the coating zone, subsequent to the coating process, to help understanding the deposited material profile across the substrate (width and length). The collected measurement data can then be used to achieve further fine-tuning of the sputtered material flux at or near the substrate surface, by adjusting one or more of the following: changing a control parameter in the control loop executed on the control unit, changing a shield opening, tuning the position and/or orientation of the magnetic assembly (globally and/or locally) via adjusted control trajectories for the actuators.

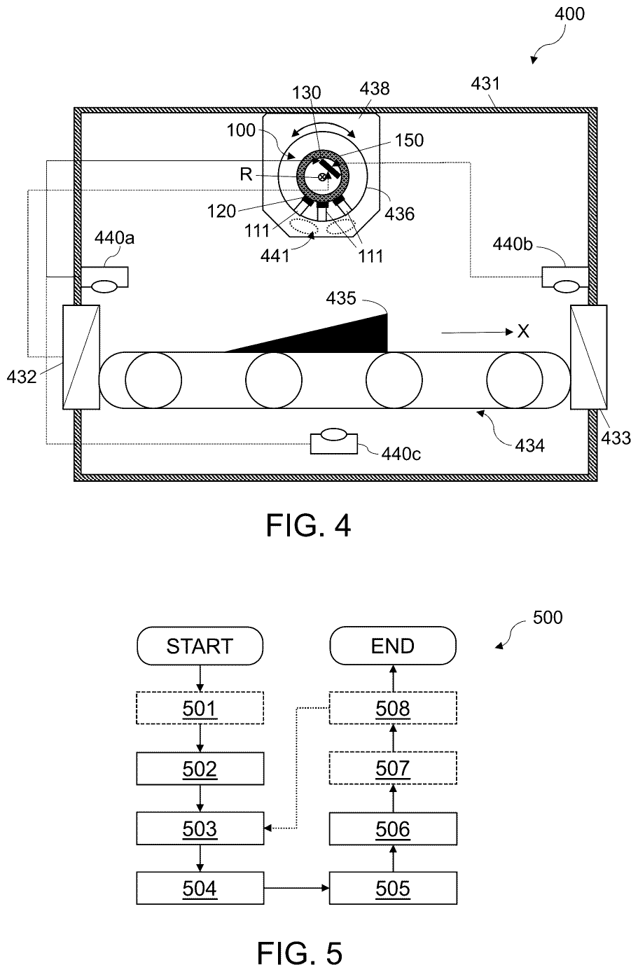

The present invention is also directed to the use of a magnetron sputter apparatus according to embodiments of the second aspect in the process of sputter-coating a moving substrate that has a non-planar surface to be coated. An exemplary method 500 of sputter-coating a curved substrate is now explained with reference to FIG. 5. Typically, the sputter target is rotated about its rotation axis during the sputter process.

The sputter-coating process 500 comprises the step 501 of storing control inputs in a storage device arranged inside a magnet bar assembly of the magnetron sputter apparatus. The control inputs comprise setpoints for at least one actuator of the magnet bar assembly or data required for the calculation of setpoints for the at least one actuator of the magnet bar assembly. In the most simple configuration of substrate and sputter coating process, this may be a single setpoint or a homing position. The control inputs may be stored at different moments in time on the storage device, e.g. following manufacture of the storage device, during or following assembly of the magnet bar assembly containing the storage device, prior to loading the substrate into a deposition chamber of the magnetron sputter apparatus, or even during movement of the substrate. It is possible to regularly update or replace control inputs, e.g. as part of a feedback control loop or upon changing the sputter process, modifying the configuration or settings of the sputter equipment, changing the product, and/or changing the substrate shape or material. The control data, e.g. the setpoints of the actuators, may be organized into lists or tables. These lists or tables may have associated therewith a unique identifier that can be used by the control unit to access a particular one list or table. Lists or tables with different identifiers may be generated and stored for different combinations of sputter equipment parameters, sputter process parameters and substrate parameters or types. For instance, unique identifiers may be assigned to tables of combinations of sputter target material, sputter target lifetime, target-to-substrate minimum distance. The parameter combination may be included in metadata or as a header of the table that contains precomputed actuator setpoint entries for this parameter combination.

The sputter-coating process further comprises the step 502 of loading the control inputs from at least one storage device into the control unit of the magnet bar assembly. Control inputs may be loaded in a serial or parallel fashion and may be accessed from different location in the same memory module or different memory modules of the storage device. The storage device may be a distributed memory.

Furthermore, the method includes the step 503 of determining a control trajectory for the at least one actuator of the magnet bar assembly based on the loaded control inputs. Determining the control trajectory of an actuator may comprise one or more of the following: obtaining a list of regulation positions by copying the loaded setpoints, obtaining additional setpoints by interpolation between loaded setpoints, performing a calibration operation on the setpoints. In alternative embodiments of the invention, control inputs may relate to local sputter rates computed for each point of a grid overlaying the substrate surface to be coated or substrate surface height in each point of a grid overlaying the substrate surface to be coated. The control inputs may be representing other data pertaining to the substrate topography or a property of the layer to be coated on the substrate surface.

A sequence of control signals for the at least one actuator is generated in step 504 in accordance with the determined control trajectory. This step may include encoding the regulation positions of the control trajectory for transmission over a communication link inside the magnet bar assembly; and transmitter-sided error coding may be performed. The control data to be transmitted may also be prepared depending on the transport protocol between the control unit and the driver circuits of the actuators. The control data may be placed into frames and driver circuit address data may be included in the frames as well. The preceding examples for this step are not exhaustive.

The method further comprises step 505 of receiving an external trigger signal from a trigger unit, e.g. substrate position sensor unit or an output of the substrate transport system, disposed distantly to the magnet bar assembly, while loading the curved substrate to be coated into the deposition chamber or transporting the substrate past the sputter source, and step 506 of synchronizing the transmission of the sequence of control signals to the driver circuit of the at least one actuator with a trigger signal from a remote trigger unit, i.e., external to the magnet bar assembly. This step may include extracting a substrate position from the trigger signal and combining the extracted substrate position with substrate movement data, e.g. substrate speed, to calculate a start time or delay for transmission of the first control signal of each sequence of control signal. An internal timer or counter of the control unit may be reset or programmed accordingly. The substrate movement data may be extracted from the trigger signal too, or may be accessed from the storage device or communicated to the control unit as external data via a communication link. Based on the trigger signal or further trigger signals, timing information for the transmission of the transmission of the subsequent control signals of each sequence of control signals can also be derived and/or improved by the control unit. During transport, the substrate is typically mounted onto a carrier or frame of a horizontal or substantially vertical transport system such as a roller-based or a belt-based conveyor system. Preferably, the curved substrate is oriented relative to the magnet bar assembly such that an axis of curvature of the curved substrate is maintained during transport.

The driving circuit of the at least one actuator receives the transmitted control signals in step 507 and coverts each (decoded) control signal into a corresponding drive signal, e.g. PWM signal, thereby moving/rotating the actuator to a new position/rotation angle. This in response locally adjusts the position and/or orientation of the magnetic structure of the magnet bar assembly.

The actual position of the actuators after regulation by the driver circuits may be measured in step 508. This measurement may provide feedback information to the control unit that is capable of running a control loop. The feedback information is compared to desired regulation positions of the control trajectories and possible deviations are detected by the control unit. Then, the control unit or even logic within the driver circuits may re-adjust or transform the regulation positions of the control trajectories based on the received feedback information. Alternatively or additionally, feedback information may also stem from substrate measurements behind the coating zone, e.g. measurements related to a property of the coated layer.

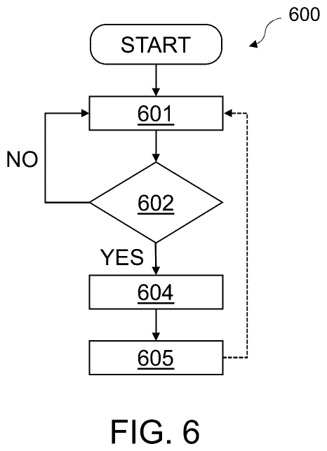

An exemplary method 600 of updating or adjusting control trajectories for the control assembly actuators is now explained with reference to FIG. 6.

In a first step 601, the control unit is listening and waiting for an interrupt signal that conveys information about a parameter change. Reception of the interrupt signal may suspend the generation of control signals by the control unit, or the loading of new actuator setpoints from the storage device(s). Current calculation of control trajectories for the control assembly actuators may be aborted. The interrupt signal may originate from the external trigger unit, the substrate transport system, metrology equipment, or sensor units that are located outside the control assembly. Sensors within the control assembly may also raise such an interrupt signal, e.g. a temperature sensor or a magnetic field sensor sensing corresponding variables at or near the target surface. The aforementioned parameter change corresponds to a change in a process variable, a change in substrate property or type, or and/or a change in the equipment settings, which influence the required sputter flux and thus require local adjustment of the position and/or orientation of the magnetic structure. Parameter changes that cause an interrupt signal may include, amongst others, a new production campaign may be started with a different target material, a change in the working gas pressure during a running production campaign may be detected, a deviation in the initial substrate or coated substrate topography or material properties may be detected while running of a production campaign, a detected change of substrate dimensions or orientation, or a parameter change initiated in response to a user input. A user may also provide a new configuration of the magnetic structure which overrides the existing configuration and requires the determination of new actuator setpoints.

Decision step 602 regularly verifies whether a (valid) interrupt signal is received that requires an adjustment of the control trajectories. If no or no valid interrupt signal is received at this moment in time, the control unit continues with step 601 and waits for possible interrupt signals to arrive. If a valid interrupt signal is received in step 602, the control unit continues with step 603.

In step 603, the control unit calculates changes to the setpoint(s) for the at least one actuator that are caused or likely to be caused by the parameter change. The changes may be calculated as correction factors to be used as scaling factors when adjusting the control trajectories in step 605. Likeliness may be defined by a set of rules that indicate beyond which threshold value for the one or multiple parameter that is being changed, a recalculation of the actuator setpoints is necessary. Rule-based recalculation of the setpoints and threshold values may be provided based on user preferences and/or derived from system specifications.

In step 604, the control unit is updating the setpoint(s) for the at least one actuator in accordance with the calculated changes to the setpoint(s). The updated values may be written back to the at least one storage device, e.g. overwriting the previously stored setpoints, e.g. of a particular table, or creating a new table with the updated setpoints as entries. A local copy of the updated setpoint(s) and/or a reference to the memory location in the at least one storage device that contains the updates setpoint(s) may be maintained in the control unit.

Next, the control unit is adjusting the control trajectory for the at least one actuator in accordance with the updated setpoint(s) in step 605. Thereafter, the control unit may return to step 601 if the sputter-coating process is still active and running.

In a variant of this method, actuator setpoint changes are not calculated, but more adequate setpoints are loaded from the at least one storage device. The interrupt signal may contain an identifier or allow the derivation of an identifier that the control unit uses to access a particular memory location or region in the at least one storage device, e.g. an identifier which allows access to a specific table of actuator setpoints that are compatible and optimal with respect to the change in parameters.

While the invention has been illustrated and described in detail in the drawings and foregoing description, such illustration and description are to be considered illustrative or exemplary and not restrictive. The foregoing description details certain embodiments of the invention. It will be appreciated, however, that no matter how detailed the foregoing appears in text, the invention may be practiced in many ways. The invention is not limited to the disclosed embodiments.

Other variations to the disclosed embodiments can be understood and effected by those skilled in the art in practicing the claimed invention, from a study of the drawings, the disclosure and the appended claims. In the claims, the word “comprising” does not exclude other elements or steps, and the indefinite article “a” or “an” does not exclude a plurality. A single processor or other unit may fulfill the functions of several items recited in the claims. The mere fact that certain measures are recited in mutually different dependent claims does not indicate that a combination of these measures cannot be used to advantage. Any reference signs in the claims should not be construed as limiting the scope.

1-16. (canceled)

17. An assembly for controlling a magnetic structure of a magnetron sputter apparatus, the assembly being connectible to an end block of the magnetron sputter apparatus and comprising:
an elongate support structure and, coupled to the support structure,
at least one control unit, at least one storage device and at least one actuator for locally adjusting a position and/or orientation of the magnetic structure,
wherein an input connector of the at least one control unit is operatively connectible to a trigger unit disposed distantly to the assembly, and
wherein the at least one control unit is configured to:
load control inputs from the at least one storage device, wherein control inputs comprise setpoints for the at least one actuator or data required for the calculation of setpoints for the at least one actuator,
determine a control trajectory for the at least one actuator based on the control inputs,
generate a control signal or sequence of control signals for the at least one actuator in accordance with the control trajectory, and
synchronize a transmission of the control signal or the sequence of control signals to a driver circuit of the at least one actuator with at least one trigger signal from the trigger unit, said at least one trigger signal being indicative of a position of a substrate relative to the magnetic structure.

18. The assembly according to claim 17, wherein the magnetic structure is connectible to a support member of the support structure via the at least one actuator.

19. The assembly according to claim 17, wherein the at least one control unit is further configured to:
load a record of one or more process variables pertaining to the magnetron sputter apparatus from the at least one storage device or from the trigger unit through the input connector, and
adjust the control trajectory based on said record of said one or more process variables.

20. The assembly according to claim 17, wherein the at least one control unit is further configured to:
receive substrate trajectory information related to the movement of a substrate past the assembly, and
determine time intervals between the transmission of two consecutive control signals of the sequence of control signals based on the substrate trajectory information.

21. The assembly according to claim 20, wherein the at least one control unit is further configured to load the substrate trajectory information from the at least one storage device or extract the substrate trajectory information from the trigger signal from the trigger unit.

22. The assembly according to claim 20, wherein the at least one control unit is further configured to extract substrate position and/or substrate speed information conveyed by the trigger signal from the trigger unit and calculate a delay for transmitting a control signal of the sequence of control signals relative to the trigger signal from the trigger unit based on the substrate position and/or substrate speed information.

23. The assembly according to claim 17, wherein the control inputs comprise substrate surface topography related data and the at least one control unit further comprises a data processing subunit configured to calculate setpoints for the at least one actuator based on the surface topography related data.

24. The assembly according to claim 17, wherein the at least one control unit is further configured to:
extract substrate geometry information and/or sputter process conditions conveyed by the trigger signal from the trigger unit,
identify the control inputs to be loaded from the at least one storage device based on the substrate geometry information and/or sputter process conditions.

25. The assembly according to claim 17, comprising a single or multiple control units and a plurality of actuators for locally adjusting the position and/or orientation of the magnetic structure at different locations along the support structure,
wherein the single or multiple control units is configured to generate the control trajectory for the plurality of actuators.

26. The assembly according to claim 17, wherein the at least one actuator is an electrically driven actuator, a pneumatic actuator, or a hydraulic actuator.

27. The assembly according to claim 17, wherein the at least one storage device is a persistent memory device.

28. A magnetron sputter apparatus for sputter-coating of a non-flat substrate, comprising the assembly according to claim 17, a magnetic structure coupled to the support structure via the at least one actuator, a sputter target mounted substantially coaxially over the support structure, and an end block system connected to the assembly and the sputter target.

29. An inline vacuum sputter coating apparatus for generating repetitive and reproducible coating profiles on moving substrates, the inline vacuum sputter coating apparatus comprising:
the magnetron sputter apparatus of claim 28,
a transport system for moving the substrates past the magnetron sputter apparatus, and
the trigger unit for generating trigger signals conveying information related to a substrate position along the transport system,
wherein the at least one trigger unit is configured to transmit a trigger signal to the at least one control unit upon the detection of events that locate individual ones of the substrates along the transport system.

30. A method of sputter-coating a moving substrate, using a magnet bar assembly for a magnetron sputter apparatus, the magnet bar assembly comprising at least one actuator for locally adjusting a position and/or orientation of an elongate magnetic structure of the magnet bar assembly, the method comprising:
storing control inputs in a storage device arranged inside the magnet bar assembly, wherein the control inputs comprise setpoints for the at least one actuator or data required for the calculation of setpoints for the at least one actuator,
loading the control inputs from the storage device into a control unit arranged inside the magnet bar assembly,
receiving an external trigger signal from a trigger unit disposed distantly to the magnet bar assembly, said external trigger signal being indicative of a position of the substrate relative to the magnetic structure,
executing a control program on the control unit to determine a control trajectory for the at least one actuator based on the control inputs, generate a control signal or a sequence of control signals for the at least one actuator in accordance with the control trajectory, and synchronize a transmission of the control signal or the sequence of control signals to a driver circuit of the at least one actuator with the external trigger signal,
adjusting the position and/or orientation of magnetic structure while sputter-coating the moving substrate, by driving the at least one actuator in accordance with the control signals or the sequence of control signals.

31. The method of claim 30, wherein storing control inputs in the storage device includes storing sputter process parameters and/or surface topography related data for the coating of non-flat substrate surfaces, and the method further comprising calculating the setpoints for the at least one actuator based on the process parameters and the surface topography related data.

32. The method of claim 30, further comprising:
calculating changes to the setpoints for the at least one actuator caused by a change in at least one of a process variable of the sputter-coating method and a parameter of the magnetron sputter apparatus comprising the magnet bar assembly,
updating the setpoints for the at least one actuator stored in the storage device in accordance with the changes to the setpoints, or
adjusting the control trajectory for the at least one actuator in accordance with the changes to the setpoints.
